(19) United States
(12) Patent Application Publication
(10) Pub. No.: US 2008/0298020 A1
(43) Pub. Date: Dec. 4, 2008

(54) Heat dissipation device having holes

(75) Inventors: He-Kang Zhou, Shenzhen (CN); Tong Zhou, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/810,405

(22) Filed: Jun. 4, 2007

(30) Foreign Application Priority Data
Jun. 2, 2007 (TW) 95119602

(51) Int. Cl. H05K 7/20

(52) U.S. Cl. 361/704

(57) ABSTRACT

An exemplary heat dissipation device (20) includes a base (21) and heat dissipation fins (22) extending from the base. Each heat dissipation fin has ventholes (23) formed therein. An area of an inner surface of each venthole is greater than twice an area of a transverse cross-section of the venthole. The heat dissipation device has a high heat dissipation efficiency.

### FIELD OF THE INVENTION

The present invention relates to a heat dissipation device typically used in or with electronic heat-generating apparatuses, and particularly to a heat dissipation device with a large heat dissipation area.

### GENERAL BACKGROUND

Electronic devices such as central processing units (CPUs) of computers generate large amounts of heat during their normal operation. The heat must be quickly removed to keep the CPU working within its normal temperature range. Typically, a heat dissipation device is installed with the CPU in order to facilitate heat dissipation.

Conventional heat dissipation devices include aluminum extrusion type heat dissipation devices. The extrusion heat dissipation device is integrally formed by a molding and extrusion method, and generally includes a heat dissipation base and a plurality of cooling fins extending from the base. The cooling fins provide the extrusion heat dissipation device with an increased heat dissipating surface area. However, due to inherent limitations of molding and extrusion technology, a height of the fins of the extrusion heat dissipation device is limited and the spaces between adjacent fins cannot be configured as narrowly as desired. The density of the fins is therefore limited, and this significantly restricts the heat dissipation surface area of the extrusion heat dissipation device.

Referring to FIG. 7, a typical heat dissipation device 10 includes a heat transferring base 11, and a plurality of heat dissipation fins 12 extending vertically from the base 11. In a typical application, the heat dissipation device 10 is soldered or fixed on a printed circuit board (PCB) 1. The PCB 1 has a plurality of electronic elements and chips attached thereon. The heat dissipation fins 12 are parallel to each other, and are spaced a predetermined distance apart from each other by a plurality of channels 13.

When the electronic elements and chips are operating, heat generated by them is transferred to the PCB 1 and then to the base 11 and the heat dissipation fins 12. The heat is then diffused to the ambient air via the whole surface of the heat dissipation device 10.

Because of the planar configuration of the heat dissipation fins 12 and the channels 13 therebetween, heat in the air in the channels 13 can only flow in directions substantially parallel to the heat dissipation fins 12. In other words, when the heat dissipates from the channels 13 to an exterior of the heat dissipation device 10, the directions of flow of the heat are limited. Correspondingly, the heat dissipation efficiency of the heat dissipation device 10 is restricted. Furthermore, if a greater dissipation surface area is desired in order to increase the heat dissipation efficiency, a larger sized base 11 and/or more heat dissipation fins 12 are needed. This means the heat dissipation device 10 occupies a larger volume.

What is needed, therefore, is a heat dissipation device that can overcome the above-described deficiencies.

### SUMMARY

In one preferred embodiment, a heat dissipation device includes at least one heat dissipation fin. The at least one heat dissipation fin has a plurality of heat dissipation spaces formed therein.

Other novel features and advantages of the present heat dissipation device will become more apparent from the following detailed description when taken in conjunction with the accompanying drawings. In the drawings, all the views are schematic.

### BRIEF DESCRIPTION OF THE DRAWINGS

FIG. 1 is an isometric view of a heat dissipation device according to a first embodiment of the present invention, showing the heat dissipation device installed on a printed circuit board (PCB).

FIG. 2 is an isometric view of a heat dissipation device according to a second embodiment of the present invention, showing the heat dissipation device installed on a PCB.

FIG. 3 is an isometric view of a heat dissipation device according to a third embodiment of the present invention, showing the heat dissipation device installed on a PCB.

FIG. 4 is an isometric view of a heat dissipation device according to a fourth embodiment of the present invention.

FIG. 5 is an isometric view of a heat dissipation device according to a fifth embodiment of the present invention.

FIG. 6 is an isometric view of a heat dissipation device according to a sixth embodiment of the present invention.

FIG. 7 is an isometric view of a conventional heat dissipation device, showing the heat dissipation device installed on a PCB.

### DETAILED DESCRIPTION OF PREFERRED EMBODIMENTS

Reference will now be made to the drawing figures to describe various embodiments of the present invention in detail.

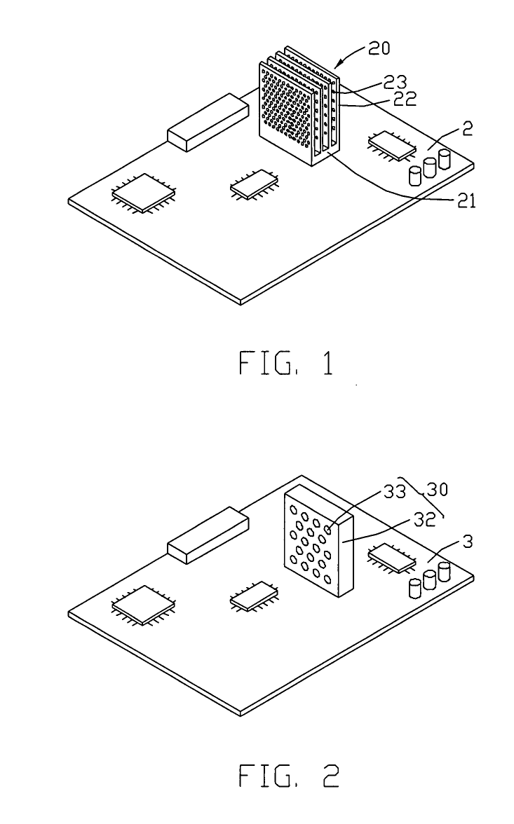

FIG. 1 shows a heat dissipation device 20 according to a first embodiment of the present invention. The heat dissipation device 20 is mounted on a printed circuit board (PCB) 2 by way of soldering or other suitable means. The PCB 2 has a plurality of electronic elements and chips attached thereon. The heat dissipation device 20 includes a base 21, and a plurality of heat dissipation fins 22 extending perpendicularly from the base 21. Typically, the heat dissipation device 20 is made by a molding and extrusion method. In other words, the heat dissipation fins 22 and the base 21 are integrally formed as a single body. The heat dissipation fins 22 are substantially plate-shaped or board-shaped, and are parallel to each other. The base 21 and the heat dissipation fins 22 can be made from material including at least one of aluminum (Al) and copper (Cu). The heat dissipation fins 22 can be attached on the base 21 by a low thermal resistance bonding or adhesive material such as tin solder.

Each heat dissipation fin 22 includes a plurality of ventholes 23 arranged in a regular array. In the illustrated embodiment, the ventholes 23 are arranged in a matrix consisting of offset rows of the ventholes 23. The ventholes 23 are columnar, and each venthole 23 spans an entire width of the heat dissipation fin 22. A radius of each venthole 23 is less than a thickness of the heat dissipation fin 22. Thereby, an area of an inner surface of the venthole 23 is greater than twice an area of a transverse cross-section of the venthole 23. As a result, an overall heat dissipation surface area of the heat dissipation device 20 is increased, and thus the heat dissipation efficiency of the heat dissipation device 20 is improved.

In the heat dissipation device 20, all the heat dissipation fins 22 have the ventholes 23, and the ventholes 23 of adjacent heat dissipation fins 22 cooperatively provide heat flow paths that are perpendicular or substantially perpendicular to the heat dissipation fins 22. That is, unlike in a conventional heat dissipation device, heat can flow not only in directions parallel to the heat dissipation fins 22, but also in directions perpendicular to the heat dissipation fins 22. Thus heat in the air between the heat dissipation fins 22 and in the ventholes 23 can flow to an exterior of the heat dissipation device 20 speedily and efficiently. Accordingly, the heat dissipation efficiency of the heat dissipation device 20 is further improved.

Referring to FIG. 2, this shows a heat dissipation device 30 according to a second embodiment of the present invention. The heat dissipation device 30 includes a single heat dissipation fin 32. The heat dissipation fin 32 is directly attached on a PCB 3. The heat dissipation fin 32 has a plurality of ventholes 33 arranged in a regular array. In the illustrated embodiment, the ventholes 33 are arranged in a matrix consisting of offset rows of the ventholes 33. Unlike the heat dissipation device 20, the heat dissipation device 30 has no base. Thus the heat dissipation device 30 occupies a smaller volume than the heat dissipation device 20.

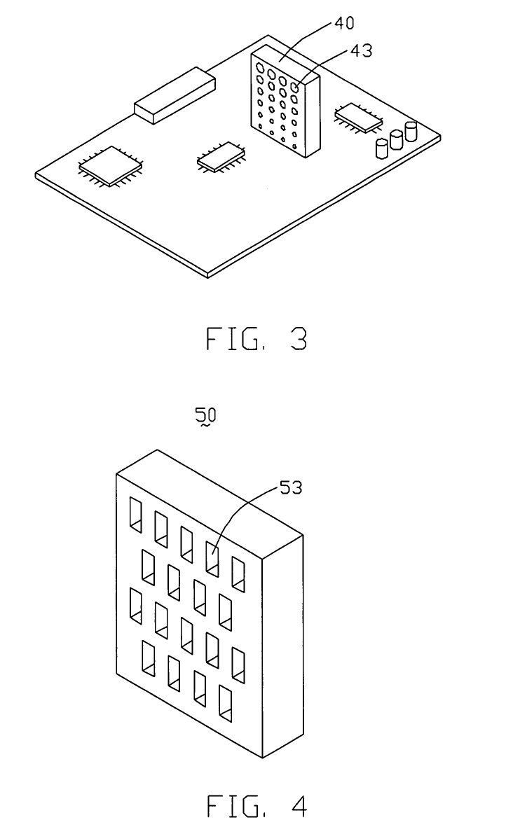

Referring to FIG. 3, this shows a heat dissipation device 40 according to a third embodiment of the present invention. The heat dissipation device 40 is similar to the heat dissipation device 30. However, a plurality of ventholes 43 are arranged in a regular m×n matrix. Further, an area of a transverse cross-section of the ventholes 43 progressively increases with increasing distance away from a PCB (not labeled). In the illustrated embodiment, an area of a transverse cross-section of the ventholes 43 increases exponentially with increasing distance away from the PCB.

Referring to FIG. 4, this shows a heat dissipation device 50 according to a fourth embodiment of the present invention. The heat dissipation device 50 is similar to the heat dissipation device 30. However, each of a plurality of ventholes 53 has a rectangular transverse cross-section.

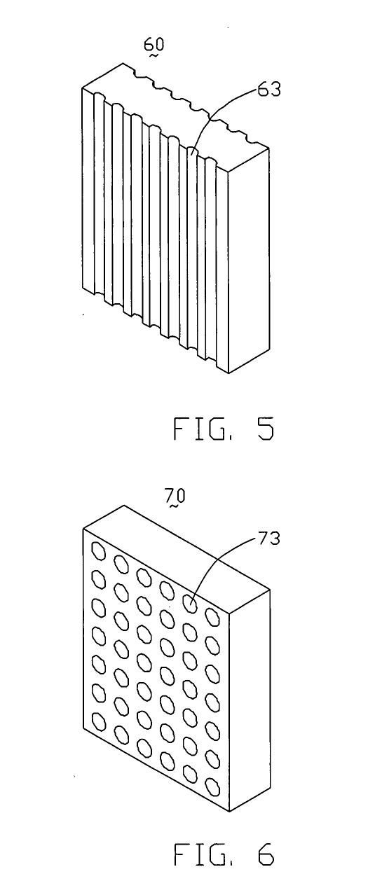

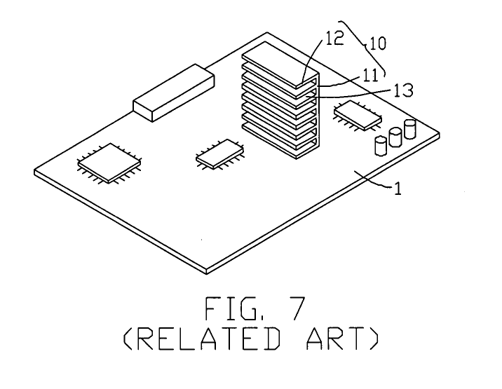

In further and/or alternative embodiments, any fin of a heat dissipation device can include a plurality of blind holes and/or a plurality of grooves. Referring to FIG. 5, this shows a heat dissipation device 60 according to a fifth embodiment of the present invention. A single fin of the heat dissipation device includes a plurality of grooves 63. The grooves 63 are defined in each of two opposite main faces of the fin. The grooves 63 are parallel to each other, and span from a top of the fin to a bottom of the fin. The fin provides the heat dissipation device 60 with an increased total heat dissipation surface area. Referring to FIG. 6, this shows a heat dissipation device 70 according to a sixth embodiment of the present invention. A single fin of the heat dissipation device includes a plurality of dimples (or pits) 73. The dimples 73 are defined in each of two opposite main faces of the fin. At each main face, the dimples 73 are arranged in a regular m×n matrix. The fin provides the heat dissipation device 70 with an increased total heat dissipation surface area.

It is to be understood, however, that even though numerous characteristics and advantages of the present embodiments have been set out in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation device, comprising:
at least one heat dissipation fin, the at least one heat dissipation fin having a plurality of spaces formed therein, the spaces configured for providing the at least one heat dissipation fin with a greater surface area for heat dissipation.

2. The heat dissipation device as claimed in claim 1, wherein the spaces are ventholes.

3. The heat dissipation device as claimed in claim 2, wherein, an area of an inner surface of each venthole is greater than twice an area of a transverse cross-section of the venthole.

4. The heat dissipation device as claimed in claim 1, wherein the spaces are selected from the group consisting of blind holes, dimples, pits, and grooves.

5. The heat dissipation device as claimed in claim 1, further comprising a base, wherein the at least one heat dissipation fin extends from the base.

6. The heat dissipation device as claimed in claim 5, wherein the at least one heat dissipation fin is soldered on the base.

7. The heat dissipation device as claimed in claim 5, wherein the at least one heat dissipation fin and the base are integrally formed as a single body.

8. The heat dissipation device as claimed in claim 5, wherein the at least one heat dissipation fin is perpendicular to the base.

9. The heat dissipation device as claimed in claim 5, wherein the base is made from material including at least one of aluminum and copper.

10. The heat dissipation device as claimed in claim 1, wherein the at least one heat dissipation fin is a plurality of heat dissipation fins, and the heat dissipation fins are separate from and parallel to each other.

11. The heat dissipation device as claimed in claim 10, wherein the spaces are ventholes, and the ventholes of adjacent heat dissipation fins cooperatively provide heat flow paths that are substantially perpendicular to the heat dissipation fins.

12. The heat dissipation device as claimed in claim 2, wherein the ventholes are columnar.

13. The heat dissipation device as claimed in claim 12, wherein a radius of each venthole is less than a thickness of the at least one heat dissipation fin.

14. The heat dissipation device as claimed in claim 2, wherein each venthole has a rectangular transverse cross-section.

15. The heat dissipation device as claimed in claim 2, wherein the ventholes are arranged in a regular repeating array.

16. The heat dissipation device as claimed in claim 2, wherein the at least one heat dissipation fin is made from material including at least one of aluminum and copper.

17. The heat dissipation device as claimed in claim 2, wherein an area of a transverse cross-section of each venthole progressively increases from one end of the at least one heat dissipation fin to an opposite end of the at least one heat dissipation fin.

18. A heat dissipation device, comprising:
at least one heat dissipation fin, the at least one heat dissipation fin having a plurality of holes formed therein, increasing a total heat dissipation surface area of the heat dissipation device.

19. The heat dissipation device as claimed in claim 18, wherein the holes are ventholes.

20. The heat dissipation device as claimed in claim 19, wherein a radius of each venthole is less than a thickness of the at least one heat dissipation fin.
